(19) United States
(12) Patent Application Publication
(10) Pub. No.: US 2014/0268654 A1
(43) Pub. Date: Sep. 18, 2014

(54) ADAPTABLE BEZEL ASSEMBLY FOR EXTREME SERVICE CONDITIONS

(71) Applicant: C-Marine Dynamics, Inc., Hampton, NH (US)

(72) Inventor: Charles J. Wagner, Stratham, NH (US)

(73) Assignee: C-Marine Dynamics, Inc., Hampton, NH (US)

(21) Appl. No.: 14/211,951

(22) Filed: Mar. 14, 2014

Related U.S. Application Data
(60) Provisional application No. 61/791,365, filed on Mar. 15, 2013.

(51) Int. Cl. H05K 9/00

(52) U.S. Cl. CPC H05K 9/0054
USPC 362/97.1; 361/809

(57) ABSTRACT

A display assembly includes a first bezel part and a second bezel part each defining a substantially rectangular frame that encloses an open area. The first frame is sized and arranged to substantially align with the second frame. The second bezel part is capable of secure attachment to the first bezel part at an interface that defines at least one gap between the first frame and the second frame. A display screen has a display edge portion disposed in the gap between the first frame and the second frame. The display screen extends across the open area. Optionally, the display assembly includes an EMI screen and/or a touch screen aligned with the display screen and having an edge portion received in the gap, where the EMI screen, display screen, and touch screen are each individually removable from the display assembly.

### BACKGROUND OF THE INVENTION

1. Field of the Invention

The present invention relates generally to electronic display equipment and more particularly to a bezel for devices with display screens.

2. Description of the Prior Art

Display screens, such as liquid crystal displays (LCDs), touch screens, and Em-IO screens, are used in a wide variety of indoor and outdoor environments. Some extreme environments damage or render these displays inoperable due to high levels of shock, vibration, moisture or water, or electromagnetic interference.

Previous design approaches to meeting the requirements of such extreme service has been to laminate the various display hardware components—LCD panel, electromagnetic interference (EMI) screen, backlighting assembly, etc.—into a single monolithic package. An example of this design approach is an LCD display assembly having a laminated LCD display module mounted between a display bezel and display case, where components of the LCD display module are bonded together.

Electronics manufacturers and others will buy laminated LCD display assemblies from a third-party manufacturer who specializes in making LCD display units. The electronics manufacturer will insert the laminated display assembly into a case as part of a permanent assembly. For reasons of durability, preventing movement between display components, and preventing parallax from improperly aligned display components, the manufacturer of the completed unit uses a laminated display assembly. If the display assembly becomes damaged or fails, the entire laminated assembly or the entire completed product is replaced.

### SUMMARY OF THE INVENTION

A major disadvantage of the above-described approach to display bezels is that the resulting product is not component serviceable. That is, the failure of any one of the hardware components of laminated LCD display module requires replacement of the entire combined laminate package. For example, a cracked display cover or defective backlighting component cannot be replaced individually, but instead must be replaced by installing a new laminated LCD display module.

An additional disadvantage is that display assemblies are not adaptable to a change in the requirements of any one component. For example, a change in the required dB level of the EMI screen requires the replacement of the entire laminated display module, not just replacement of the EMI screen. For the same reason, other damaged components require replacement of the entire laminated display module.

The need to replace the entire laminated display module is costly. Also, the above approach is inflexible to changes or improvements to the device components, particularly when a replacement component has a different dimension (e.g., thickness) than the component being replaced.

An additional limitation of conventional approaches is the difficulty in satisfying military specification MIL-S-901D, such as type C shock tests for high impact mechanical shock to a subassembly or subsidiary component. Therefore, what is needed is an improved bezel architecture that is adaptable to component changes and suitable for use in extreme service environments.

The present invention overcomes these limitations by providing a bezel assembly that allows each item in the display assembly to be independently modified or replaced at any time. For example, a change in a dB requirement for an EMI screen can be met by disassembling the bezel assembly, removing the existing EMI screen, and replacing it with a different EMI screen that satisfies the new dB requirement. This service procedure may be independently performed for each component of the combined display product.

In one embodiment of the present invention, A display assembly includes a first bezel part defining a substantially rectangular first frame enclosing a first open area and a second bezel part defining a second substantially rectangular second frame enclosing a second open area. The first frame is sized and arranged to substantially align with the second frame. The second bezel part is capable of secure attachment to the first bezel part at an interface that defines at least one gap between the first frame and the second frame. The assembly includes a display screen and having a display edge portion, where the display edge portion disposed in the gap between the first frame and the second frame. The display screen extends across the first open area and is removable from the display assembly. The assembly optionally includes an EMI screen having an edge portion, where the edge portion of the EMI screen is disposed in the gap between the first frame and the second frame and directly contacts the second bezel part. The EMI screen extends across the second open area.

In another embodiment, the display assembly optionally includes a touch screen with a touch screen edge portion received in the gap between the first and second frames with the touch screen aligned with the display screen. The touch screen extends across the first open area and is aligned with the display screen. The touch screen is individually removable from the assembly.

In another embodiment, the display assembly includes a light distribution panel disposed against the second bezel part, such as against a rear surface. The light distribution panel extends across the second open area and has an edge portion. A light source is disposed adjacent the edge portion of the light distribution panel. The light source and the light distribution panel are sized and arranged to provide backlighting to the display screen. In one embodiment, the light source comprises a plurality of LEDs disposed along the edge portion of the light distribution panel with the plurality of LEDs directed to emit light into the edge portion of the light distribution panel.

In another embodiment, the display assembly includes a front cover hingedly attached to a front surface of the first bezel part and operable between a closed position and an open position. A gasket disposed between the front cover and the first bezel part is capable of forming a water tight seal between the first bezel part and the front cover when the front cover is in the closed position.

In another embodiment, the display edge portion has a U-shaped edge gasket applied thereto. When an EMI screen is present the U-shaped edge gasket directly contacts the EMI screen and the first bezel part along the gap between the first and second bezel parts. In one embodiment, a touch screen edge portion is also received in the U-shaped edge gasket.

In another embodiment, the first bezel part and the second bezel part are made of a rigid material capable of transmitting shock waves through the display assembly, thereby preventing a shock wave from combining with shock wave energy stored within the first bezel part or the second bezel part

In another embodiment, the display assembly is capable of passing shock qualification tests of MIL-S-901D type C for a subassembly.

In another embodiment, the first bezel part and the second bezel part are made of aluminum and each have an overall thickness of at least 0.3 inch. In one embodiment, the first bezel part has an overall thickness of at least 0.35 inch.

In another embodiment, the second bezel part has an overall thickness of at least 0.45 inch. In one embodiment, the second bezel part has an overall thickness of about 0.50 inch.

In another embodiment, the display assembly includes a gasket disposed between the first frame and the second frame, where the gasket has a closed loop geometry and is capable of providing a water-tight seal between the first frame and the second frame. In one embodiment, the gasket is electrically conductive and capable of attenuating electromagnetic interference.

### BRIEF DESCRIPTION OF THE DRAWINGS

FIG. 1 illustrates a perspective view of one embodiment of a display assembly of the present invention with a cover in a closed position.

FIG. 2 illustrates a side view of the display assembly of FIG. 1 showing the split-bezel assembly and components attached thereto.

FIG. 3 illustrates a top plan view of the display assembly of FIG. 1 showing a partial cutaway to reveal the display screen and EMI panel.

FIG. 4 illustrates a side cross sectional view of the split-bezel assembly along lines A-A of FIG. 3 showing components of the display assembly of FIG. 1

FIG. 5 illustrates a top plan view of one embodiment of a top bezel part of the present invention.

FIG. 6 illustrates a cross-sectional view of the lower member of the top bezel part of FIG. 5 taken along lines B-B of FIG. 5.

FIG. 7 illustrates a cross-sectional view of the upper member of the top bezel part of FIG. 5 taken along lines C-C of FIG. 5.

FIG. 8 illustrates a top plan view of one embodiment of a bottom bezel part of the present invention.

FIG. 9 illustrates a cross-sectional view of an upper member of the bottom bezel part of FIG. 8 taken along line E-E of FIG. 8.

FIG. 10 illustrates a bottom plan view of one embodiment of a diffuser bracket of the present invention.

FIG. 11 illustrates a front elevation of the diffuser bracket of FIG. 10.

FIG. 12 illustrates a bottom plan view of the diffuser bracket of FIG. 10.

FIG. 13 illustrates a top plan view of a light tube mounting bar of the present invention showing a channel with an open end and a closed end.

FIG. 14 illustrates a front elevation of the light tube mounting bar of FIG. 13 showing openings through the lower portion.

FIG. 15 illustrates a side elevation of the light tube mounting bar of FIG. 13 showing an open end of a channel.

FIG. 16 illustrates a top plan view of a rear plate of the display assembly of FIG. 1.

FIG. 17 illustrates a side elevational view of the rear plate of FIG. 16 showing fastener standoffs.

FIG. 18 illustrates a top plan view of a front cover of the present invention.

FIG. 19 illustrates a side cross-sectional view of the front cover of FIG. 18 taken along lines F-F of FIG. 18.

FIG. 20 illustrates an exploded perspective view of one embodiment of a display assembly of the present invention.

### DETAILED DESCRIPTION OF THE PREFERRED EMBODIMENT

The preferred embodiments of the present invention are illustrated in FIGS. 1-20. FIG. 1 shows a perspective view of one embodiment of a display assembly 20 for a 12-inch control panel. Display assembly 20 has a split-bezel architecture with a top bezel part 24, and a bottom bezel part 26, and an optional front cover 22. Display assembly 20 is intended for use with LCD displays and touch screen control panels that are used in extreme service environments. The extreme service environments subject display assembly 20 to one or more conditions, such as high levels of shock, vibration, water exposure, and electromagnetic interference (EMI). In one embodiment, front cover 22 is a rectangular aluminum plate with a thickness of 0.19″. Front cover 22 is hingedly attached by hinges 31 to a top surface 28 of top bezel part 24. In one embodiment, front cover 22 is detachable from top bezel part 24. An optional handle 30 is fastened to front cover 22. Top bezel part 24 is held against bottom bezel part 26 by fasteners 32 that extend through top bezel part 24 and engage bottom bezel part 26.

FIG. 2 illustrates a side view of display assembly 20 of FIG. 1. Front cover 22 with handle 30 abuts top surface 28 of top bezel part 24. A heat sink 34 is connected to LED board 76 with a cooling fan 36 positioned to move air across fins 38 of heat sink 34, which is more clearly explained below with reference to FIG. 4. A rear plate 40 attaches to bottom bezel part 26 by being fastened to a pair of diffuser brackets 42a, 42b that are attached to rear surface 26b of bottom bezel part 26 and secure light distribution panel 64 against bottom bezel 26. In one embodiment, rear plate 40 is a rigid sheet of metal having a substantially planar, rectangular shape. Rear plate 40 in one embodiment is made of type 5052-H32 aluminum with a thickness of 0.09″ or other materials of equivalent rigidity. LED board 76 in one embodiment is a circuit board that includes LEDs used for backlighting display assembly 20. In one embodiment, a separate LED driver (not shown) is mounted inside a separate control panel (not shown) and coupled to LED board 76. LED driver delivers DC current to LEDs and/or CCFT as needed to provide the desired backlighting light intensity. In one embodiment, the LED driver supports four channels of DC current.

FIG. 3 illustrates a top plan view of display assembly 20 with a lower left portion of top cover 22 cut away to reveal an electromagnetic interference (EMI) gasket 44 disposed around and outside of the perimeter of a beveled inner face 46 of top bezel portion 24 and a portion of display screen 56.

FIG. 4 illustrates a cross-sectional view of display assembly 20 as viewed along section line A-A shown in FIG. 3. Top cover 22 abuts top bezel part 24 with EMI gasket 44 disposed therebetween. Bottom bezel part 26 has a channel 48 inset from the outer edge 26a and that is sized and shaped to accept a gasket 50. Gasket 50 forms a water-tight seal between top bezel part 24 and bottom bezel part 26 when these parts are fastened together in abutment or close proximity. The shape of channel 48 depends on the type of gasket 50 used. Gasket 50 in one embodiment is an electrically-conductive EMI shielding gasket, a waterproof gasket, an O-ring, a spacing gasket, an open and closed cell dust gasket, or the like. Gasket 50 is preferably made of polymers (e.g., EPDM, silicone, rubber, or Viton®), but may also be made of metals, or other acceptable materials known in the art. In one embodiment, channel 48 has a rectangular cross-sectional shape and gasket 50 is a 3/32″ diameter EPDM O-ring.

An inner edge 24b of top bezel part 24 extends inwardly to define a gap 52 between top bezel part 24 and bottom bezel part 26. Gap 52 receives an edge portion 55 of a display screen 56 (e.g., a touch-screen LCD display panel). In one embodiment, edge portion 55 has a U-channel edge gasket 58 that wraps around the perimeter of substrate 56 and encapsulates edge portion 55 on three sides. Edge gasket 58 in one embodiment is a U-shaped neoprene rubber channel gasket or edge trim with a closed geometry and that extends continuously along all four edges of a rectangular panel. Edge gasket 58 in one embodiment is a channel gasket made of neoprene rubber with a durometer from 45 A-75 A (“medium hard”). Typically, display screen 56 has a touch screen 54 aligned with display screen 56 and typically positioned within the bounds of edge gasket 58. Touch screen 54 provides a surface sensitive to changes in resistance, inductance, or capacitance and functions as the operator interface control for display assembly 20.

In one embodiment, touch screen 54 is a separate component from display screen 56 and is disposed between top bezel part 24 and edge gasket 58 of display screen 56. In this embodiment, an edge portion 54a of touch screen 54 is received in gap 52 with display screen 56 and EMI panel 60. In yet another embodiment, touch screen 54 directly abuts display screen 56 and has edge portion 54a received in edge gasket 58 with display screen 56. Gap 52 also receives an EMI panel or screen 60, such as a copper mesh laminated to polycarbonate. In one embodiment, EMI screen 60 has 0.001″ copper mesh with 80 openings per inch and oriented at 45° to rectangular top bezel part 24.

In the embodiment shown in FIG. 4, back side 60a of EMI panel 60 directly abuts protrusion 62 and front side 60b directly abuts edge gasket 58 of display screen 56. Edge gasket 58 on front side 56a of display screen 56 directly abuts top bezel part 24. In some embodiments, top bezel part 24 and bottom bezel part 26 define a plurality of gaps 52 to receive various layers or components in display assembly 20. These component layers include EMI panel 60, display screen 56, touch screen 54, and light distribution panel 64, for example. Gaps 52 may be defined by channels formed in, tabs or protrusions (e.g., protrusion 62) extending from, or gaps between portions of one or both of top bezel part 24 and/or bottom bezel part 26. Gaps 52 may overlap from front to back (i.e., from top bezel part 24 to bottom bezel part 26) and the number of gaps 52 is limited by the number of components and the combined thickness of the top and bottom bezel parts 24, 26.

Behind bottom bezel part 26 is a light guide or light distribution panel 64 secured against bottom bezel part 26 by diffuser bracket 42b. Light distribution panel 64 has an edge portion 66 with a front face 66a that abuts the back side of protrusion 62 of bottom bezel part 26. In one embodiment, a bottom face 66b of edge portion 66 also directly abuts a light tube mounting bar 70 fastened to the back side of bottom bezel part 26. Light distribution panel 64 has a light reflector 68 along back face 66c of edge portion 66 to illuminate light distribution panel 64 with light from cold cathode fluorescent tube (CCFT) 72 and/or from LEDs 74 on LED board 76 or in light tube mounting bar 70. Light distribution panel 64 is held in position against bottom bezel part 26 by diffuser bracket 42b. Diffuser bracket 42b is fastened directly to bottom bezel part 26 by fasteners (not shown) extending through diffuser bracket 42b into bottom bezel part. Diffuser bracket 42b is indirectly connected to bottom bezel part 26 by being fastened to a heat sink 34, which is fastened to bottom bezel part 26.

As described above and shown in FIG. 4, some gaps between individual components are filled by a gasket, such as U-shaped gasket 58 on edge portion 55 of display screen 56. In other instances, no gasket exists between components of display assembly 20 and top or bottom bezel parts 24, 26. That is, some components, such as EMI panel 60, touch screen 54, and light distribution panel 64, preferably are hard mounted in direct contact with top or bottom bezel part 24, 26 rather than having a softer, intermediate rubber gasket or other material between the component and the bezel. Being hard mounted enables bezel assembly 20 to meet shock qualification standards by transmitting, rather than storing, shock waves. A gasket or other dampening material that absorbs shock tends to transmit the reflected first shock waves where they combine with secondary shock waves stored in the material to produce a larger effective shock wave. The larger effective shock wave can cause damage to components of display assembly 20. Eliminating a gasket in some instances therefore causes shock forces to be transmitted through component parts and results in a greater ability to successfully sustain high levels of shock without damage. Preferably, display assembly 20 passes shock testing as defined in Military Specification MIL-S-901D (1989) incorporated herein by reference in its entirety.

Military specification MIL-S-901D details shock testing requirements for shipboard components, including classifications for shock grades, equipment classes, and shock test types. Grade A items are essential to the safety and continued combat capability of the ship. The unit must survive shock testing fully intact and functional. Grade B items are those whose operation is not essential to the safety and combat capability of the ship, but could become a hazard to ship operations as a result of exposure to shock. The unit is allowed to malfunction as a result of shock, but must remain fully intact due to the possibility of debris causing harm to personnel or other equipment.

Equipment Class I includes equipment required to meet shock specifications without the use of resilient or isolation mountings. Class II equipment meets shock requirements with the use of resilient mountings. Class III equipment may be mounted on a ship with or without the use of resilient mountings installed between the item and the ship structure; therefore required to meet both class I and class II requirements.

Shock Test as classified as either Type A or Type B. A Type A test is for a principal unit that is directly supported by the ship structure. A Type B test is for a subsidiary component or item that is a major part of a principal unit. A Type C test is for a subassembly that is a part of a principal unit or subsidiary component.

In one embodiment, display assembly meets type C shock testing for subassemblies. Shock testing may be conducted according to a lightweight test, a medium weight test, or a heavyweight test. For Class I tests, the assembly shall have fundamental response frequencies not lower than 25 Hz in the principal shock direction(s). For class II tests, the assembly shall possess a fundamental frequency of 12 to 16 Hz in the vertical direction.

Referring now to FIG. 5, a perspective view illustrates one embodiment of top bezel part 24. Top bezel part 24 is generally a rectangular frame with an upper member 80, a bottom member 82, a first side member 84, and a second side member 86. As also illustrated in a plan view of FIG. 7, beveled inner face 46 extends along an inside perimeter 87 of members 80, 82, 84, 86 and frames an open area 88 through which display panel 56 can be seen and touched (shown in FIG. 3). Upper member 80 and lower member 82 have recessed openings 90 for attachment to bottom bezel part 26 with machine screws or other fastener. Beveled inner face 46 is preferably beveled at about 45 degrees to top surface 28. In one embodiment, top bezel part 24 has a channel 92 extending around beveled inner face 46 to accept gasket 44 (shown in FIG. 3) for the purpose of forming a water-tight or dust-tight seal with top cover 22 and/or for EMI shielding.

FIGS. 6 and 7 show cross-sectional views of upper member 80 and lower member 82 taken along section lines C-C and B-B, respectively, of FIG. 5. In one embodiment, top bezel part 24 is made of 6061-T6 aluminum that has an overall thickness T1 of about 0.38 inch. 6061-T6 Aluminum has a modulus of elasticity of 68.9 GPa, a shear strength of 207 MPa, a tensile yield strength of 276 MPa, and a hardness of 60 on a Rockwell B scale. This material and thickness of top bezel part 24 was determined empirically to be sufficiently rigid to transmit shock waves and to reduce or prevent twisting of top bezel part 24 for a 12-inch display screen. Other materials and thicknesses are acceptable provided that top bezel part 24 sufficiently transmits shock waves rather than stores and retransmits the energy of shock waves, which can damage a display screen 56. Each of upper member 80 and lower member 82 show beveled inner face 46 and channel 92. Upper member 80 also shows recessed opening 90, which may be a through-opening or a threaded opening.

FIG. 8 illustrates a top plan view of one embodiment of bottom bezel part 26. Similar to top bezel part 24, bottom bezel part 26 is generally a rectangular frame with an upper member 94, a lower member 96, a first side member 98, and a second side member 100. Members 94, 96, 98, 100 of bottom bezel part 26 substantially align with members 80, 82, 84, 86, respectively, of top bezel part 24. An edge portion 66 extends inwardly from each of members 94, 96, 98, 100, forming a recess in bottom bezel part 26 that together with top bezel part 24 defines gap 52 to receive EMI panel 60 and display screen 56 (shown in FIG. 4). Members 94, 96, 98, 100 enclose an open area 104 where light distribution panel 64 can provide back lighting to display screen 56. An opening 101 through second side member 100 is sized and arranged for electrical connectors (not shown) of components of display assembly 20. In one embodiment, bottom bezel part 26 is made of type 6061 aluminum with an overall thickness T2 of 0.50 inch and gap 52 extending 0.312 inch into bottom bezel part 26 to edge portion 66 as indicated by arrow T3. In one embodiment designed for a 12″ display screen 56, members 94, 96 have a width W1 of about 1.97 inches with edge portion 66 occupying 0.40 inch of width W1; members 98, 100 have a width W2 of about 1.65 inches with edge portion 66 also occupying about 0.40 inch of width W2.

FIG. 9 illustrates a cross-sectional view taken along section lines E-E of upper member 94 shown in FIG. 8. As shown, for example, with upper member 94, a channel 106 extends along each of members 94, 96, 98, 100 and around the outside perimeter of edge portion 66 to accept gasket 50 (shown in FIG. 4). A plurality of recesses 108 align with recessed openings 90 of top bezel part 24 and are sized to receive fasteners 32 (shown in FIG. 1). Recesses 108 are preferably threaded bores that receive a threaded machine screw. A back face 110 of bottom bezel part 26 has a channel 112 to accept an additional gasket (not shown) and inset ledges 114a, 114b to receive a light distribution panel 64 or other assembly member so that the member is slightly recessed into back face 110 of bottom bezel part 26.

Referring now to FIGS. 10, 11, and 12, top, front, and bottom views, respectively, illustrate one embodiment of diffuser bracket 42. Diffuser bracket 42 has a longitudinal middle portion 116 connected between a first end portion 118 and a second end portion 120 that each extend substantially perpendicularly from middle portion 116 to define an elongated n-shape. Middle portion 116 has a plurality of openings 122 extending therethrough in a direction parallel to end portions 118, 120 for attachment of additional components, such as rear panel 40. Each of first end portion 118 and second end portion 120 has one (or more) openings 119 that extend therethrough in a direction parallel to their direction of extension from middle portion 116. Openings 119 accept fasteners (not shown) for attachment to bottom bezel part 26. Middle portion 116 has a plurality of openings 124 extending transversely therethrough in a direction perpendicular to openings 122 for attachment of components, such as heat sink 34. First and second end portions 118, 120 preferably define a shoulder 126, 128 with a shoulder top surface 126a, 128a below a top surface 116a of middle portion 116. Shoulders 126, 128 allow heads of fasteners extending through openings 119 to rest flush with or below top surface 116a of middle portion 116. Light distribution panel 64 is received against middle portion 116 and between end portions 118, 120 of each diffuser bracket 42. Diffuser bracket 42 in one embodiment is made of aluminum or other rigid material.

Referring now to FIGS. 13-15, top, side, and end views, respectively, illustrate one embodiment of light tube mounting bar 70. A channel 130 extends along light tube mounting bar 70 and preferably has one open end 132 and one closed end 134. Thus, light tube mounting bar 70 is a longitudinal U-shaped bar (with one closed channel end 134) of generally rectangular overall cross-sectional shape. Channel 130 is sized and adapted to accept a cold cathode fluorescent tube (CCFT) or other light source, such as an array of LEDs. In one embodiment, channel 130 has a reflective surface 130a to reflect light from the light source.

A plurality of recessed openings 138 extend transversely through a lower portion 136 of light tube mounting bar. Lower portion 136 is the portion of light tube mounting bar 70 positioned beneath channel 130. Recessed openings 138 accept fasteners (not shown) for attachment of heat sink 34 as shown in FIG. 4. A plurality of additional openings 140 extend transversely at least partially through lower portion 136 of light tube mounting bar 70. Openings 140 receive fasteners (shown in FIG. 4) for attachment of additional components, such as LED board 76 as shown in FIG. 4.

Referring now to FIGS. 16 and 17, a plan view and a side cross-sectional view, respectively, illustrate one embodiment of a protective front cover 22. Front cover 22 is a substantially planar sheet with a rectangular shape. In one embodiment, front cover 22 is made of aluminum or other rigid material. One or more recessed through-openings 140 accept fasteners (not shown) for attachment of optional handle 30 (shown in FIG. 1). Additional through-openings 142 accept fasteners (not shown) for attachment of hinges 31 or other accessories (shown in FIG. 1).

Referring now to FIGS. 18 and 19, a plan view and a side view, respectively, illustrate one embodiment of a rear plate 40. Rear plate 40 is a substantially planar sheet with a rectangular shape. In one embodiment, rear plate 40 is made of aluminum or other rigid material. Rear plate 40 has a plurality of through openings 144 and one or more additional accessory through openings 146. Through-openings 144 accept fasteners (not shown) for attachment of rear plate 40 to diffuser brackets 42a, 42b as shown in FIG. 2. Accessory through-openings 146 accept fasteners for attachment of a sub panel, cover, or other accessory (not shown). As shown in FIG. 19, front face 148 of rear plate 140 has fastener standoffs 150 aligned with accessory through-openings 146.

Referring now to FIG. 20, bezel assembly 20 of FIG. 1 is shown exploded in a rear, perspective view and includes rear panel 40, diffuser brackets 42, heat sink 34 with fan 36, LED board 76, light tube mounting bar 70, light distribution panel 64, bottom bezel part 26, EMI panel 60, display screen 56, gasket 50, top bezel part 24, and front cover 22. EMI panel 60, display screen 56, and touch screen 54 are hard mounted between top bezel part 24 and bottom bezel part 26. Gasket 58 provides a water-tight seal between top bezel part 24 and bottom bezel part 26. LED board 76 and light tube mounting bar 70 with a cold cathode fluorescent tube (CCFT) provide backlighting to light distribution panel 64, which is received in a back side 26b of bottom bezel part 26 and held in position by diffuser brackets 42. Heat sink 34 with fan 36 attach to light tube mounting bar and/or diffuser bracket 42 to provide cooling to display assembly 20. Rear panel 40 attaches to diffuser brackets 42 and includes or receives a controller (not shown) to control display screen 56 and/or LED board 76 as well as receive user input from touch screen 54.

Integrating the top bezel part 24 and bottom bezel part 26 together with other individual components provides a virtual laminated product without the permanent bonding of an actual laminate process. Embodiments of bezel assembly 20 of the present invention allow display components to be individually removed and replaced. Such adaptability is useful when individual components need to be replaced due to damage or failure or when it is desirable to replace component, such as EMI panel 60, with a similar component having different performance specifications.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

I claim:

1. A display assembly comprising:
a first bezel part defining a substantially rectangular first frame enclosing a first open area; and
a second bezel part defining a second substantially rectangular second frame enclosing a second open area, wherein the first frame is sized and arranged to align with the second frame and wherein the second bezel part is capable of secure attachment to the first bezel part at an interface that defines at least one gap between the first frame and the second frame; and
a display screen having a display edge portion disposed in the at least one gap between the first frame and the second frame, wherein the display screen extends across the first open area and is removable from the display assembly.

2. The display assembly of claim 1, further comprising a touch screen aligned with the display screen and having a touch screen edge portion disposed in the at least one gap and positioned between the first frame and the display screen, wherein the touch screen extends across the first open area and is individually removable from the display assembly.

3. The display assembly of claim 2, further comprising:
an EMI screen aligned with the display screen and having an edge portion, the edge portion of the EMI screen disposed in the at least one gap between the first frame and the second frame and directly contacting the second bezel part, wherein the EMI screen extends across the second open area, wherein the EMI screen is individually removable from the display assembly.

4. The display assembly of claim 1, further comprising:
a light distribution panel disposed against a rear surface of the second bezel part and having an edge portion, the light distribution panel extending across the second open area; and
a light source disposed adjacent the edge portion of the light distribution panel;
wherein the light source and the light distribution panel backlight the display screen.

5. The display assembly of claim 4, further comprising:
a front cover hingedly attached to a front surface of the first bezel part and operable between a closed position and an open position;
a gasket disposed between the front cover and the first bezel part and forming a water tight seal between the first bezel part and the front cover when the front cover is in the closed position.

6. The display assembly of claim 4, wherein the light source comprises a plurality of LEDs disposed along the edge portion of the light distribution panel with the plurality of LEDs positioned to emit light into the edge portion of the light distribution panel.

7. The display assembly of claim 2, wherein the display edge portion has a U-shaped edge gasket applied thereto, the U-shaped edge gasket directly contacting the first bezel part along the at least one gap.

8. The display assembly of claim 7, wherein the touch screen edge portion is received in the U-shaped edge gasket.

9. The display assembly of claim 8, further comprising an EMI screen aligned with the display screen and having an edge portion, the edge portion of the EMI screen disposed in the at least one gap between the first frame and the second frame and directly contacting the second bezel part, wherein the EMI screen extends across the second open area, wherein the EMI screen is individually removable from the display assembly.

10. The display assembly of claim 1, wherein the first bezel part and the second bezel part are each made of a rigid material capable of transmitting shock waves through the display assembly, thereby preventing a shock wave from combining with stored shock wave energy within the first bezel part or the second bezel part.

11. The display assembly of claim 10, wherein the display assembly is capable of passing a shock qualification test defined by MIL-S-901D type C for a subassembly.

12. The display assembly of claim 10, wherein the first bezel part and the second bezel part are made of aluminum and each of the first bezel part and the second bezel part has an overall thickness of at least 0.3 inch.

13. The display assembly of claim 12, wherein the first bezel part has an overall thickness of at least 0.35 inch.

14. The display assembly of claim 12, wherein the second bezel part has an overall thickness of at least 0.45 inch.

15. The display assembly of claim 1, further comprising a gasket disposed between the first frame and the second frame, wherein the gasket has a closed loop geometry and is capable of providing a water-tight seal between the first frame and the second frame.

16. The display assembly of claim 15, wherein the gasket is electrically conductive and capable of attenuating electromagnetic interference.

17. The display assembly of claim 7, wherein the U-shaped edge gasket is made of neoprene rubber having a durometer from about 45 A to about 75 A.
